(19) United States
(12) Patent Application Publication
(10) Pub. No.: US 2023/0287564 A1
(43) Pub. Date: Sep. 14, 2023

(54) DEVICES AND METHOD FOR DELIVERING MOLYBDENUM VAPOR

(71) Applicant: ENTEGRIS, INC., Billerica, MA (US)

(72) Inventors: Bryan C. Hendrix, Danbury, CT (US); Scott L. Battle, Cedar Park, TX (US); Benjamin R. Garrett, Leander, TX (US); Carlo Waldfried, Middleton, MA (US); Gavin Richards, Newtown, CT (US)

(21) Appl. No.: 18/118,300

(22) Filed: Mar. 7, 2023

Related U.S. Application Data
(60) Provisional application No. 63/317,718, filed on Mar. 8, 2022.

(51) Int. Cl. C23C 16/44; C01G 41/04; C01G 39/00

(52) U.S. Cl. CPC C23C 16/4404; C01G 41/04; C01G 39/006

(57) ABSTRACT

A device which can be exposed to chemical vapors, such as a molybdenum vapor, a tungsten vapor, or any combination thereof, which has a coating covering at least a portion thereof. The coating reduces or inhibits mass change at an outer surface of the device from exposure to the vapor. In certain situations, the mass change is a mass gain, and the coating reduces or inhibits the mass gain of equal to or less than 1×10⁻⁵ g mm⁻².

### PRIORITY

The present disclosure claims priority to U.S. provisional application No. 63/317,718 with a filing date of Mar. 8, 2022.

### FIELD

The present disclosure relates to the field of devices and methods for delivering molybdenum vapor.

### BACKGROUND

Various materials suffer from unwanted corrosion when the materials are exposed to chemical vapors, such as molybdenum vapor. Increased heat, pressure, or both can enhance the unwanted corrosion.

### SUMMARY

Corrosion in a material (e.g., metals) can be detected via measurement of mass lost in the material. Exposure to chemical vapor(s), heat, pressure, or any combination thereof, can lead to loss of mass at the exposed surface(s). This kind of mass loss can be detected and measured.

Another kind of unwanted corrosion can occur under certain conditions, where the exposed surface gains mass. That is, under particular situations, corrosion in a material (e.g., metals) can be detected via measurement of mass gain in, on, or at the exposed material. Exposure to chemical vapor(s), heat, pressure, or any combination thereof, can lead to enhanced mass gain in, on, or at the exposed surface(s) of a material. In some circumstances, the mass gain occurs prior to chemical reaction to the material which can be classified as corrosion.

Some embodiments of the present disclosure relate to protecting at least a portion of a surface of a material from mass change. Some embodiments of the present disclosure relate to protecting at least a portion of a surface of a material from mass gain. Some embodiments of the present disclosure relate to protecting at least a portion of a surface of a material from mass loss. Some embodiments of the present disclosure relate to protecting at least a portion of a surface of a material from corrosion.

In some embodiments, the mass gain is at least in part due to residues that form on a surface of a material. In some embodiments, the residues have a particular color, that is different from the normal color of the material. In some embodiments, the residues are blue or bluish. In some embodiments, the residues change the color of the material. In some embodiments, the change in the color is to a blue or bluish color. In some embodiments, the mass gain is at least in part due to molybdenum residues that form on a surface of a material. In some embodiments, the mass gain is at least in part due to tungsten residues that form on a surface of a material.

In some embodiments, a device comprising a coating covering at least a portion of the device, wherein the coating is configured for being exposed to a vapor, wherein the coating reduces or inhibits mass change at an outer surface of the device from exposure to the vapor.

In some embodiments, the vapor comprises at least one of a metal halide vapor, a metal oxyhalide vapor, or any combination thereof.

In some embodiments, the vapor comprises at least one of molybdenum, tungsten, or any combination thereof.

In some embodiments, the vapor comprises at least one of a molybdenum vapor, a tungsten vapor, or any combination thereof.

In some embodiments of the device, the mass change is a mass gain.

In some embodiments of the device, the coating reduces or inhibits the mass gain in per unit area of equal to or less than 1×10⁻⁵ g mm⁻².

In some embodiments of the device, the mass change is a mass loss.

In some embodiments of the device, the molybdenum vapor comprises at least one of MoO₂Cl₂, MoOCl₄, MoCl₅, or any combination thereof.

In some embodiments of the device, the tungsten vapor comprises at least one of WCl₆, WCl₅, WOCl₄, WO₂Cl₃, or any combination thereof.

In some embodiments of the device, the coating comprises at least one of a metal oxide, a metal alloy, an elemental metal, a quartz, or any combination thereof.

In some embodiments of the device, the coating comprises a metal oxide.

In some embodiments of the device, the metal oxide comprises at least one of an aluminum oxide, a silicon oxide, an yttrium oxide, a magnesium oxide, a calcium oxide, a zirconium oxide, a hafnium oxide, a boron oxide, or any combination thereof.

In some embodiments of the device, the coating comprises a metal alloy.

In some embodiments of the device, the metal alloy comprises less than 20% by weight of molybdenum (Mo) based on a total weight of the metal alloy.

In some embodiments of the device, the coating comprises at least one of aluminum (AI), silicon (Si), yttrium (Y), magnesium (Mg), calcium (Ca), zirconium (Zr), hafnium (Hf), boron (B), or any combination thereof.

In some embodiments of the device, the coating comprises at least one of yttria, alumina, silica, graphite, sputtered nickel, fluorinated metal alloy, polished stainless steel, borosilicate glass, or any combination thereof.

In some embodiments of the device, the mass gain is due to at least in part molybdenum residue.

In some embodiments of the device, the coating inhibits formation of the molybdenum residue on the coating when the molybdenum vapor is at a temperature of 100° C. or greater.

In some embodiments of the device, the molybdenum residue is a reaction product of a material of the device and the molybdenum vapor.

In some embodiments of the device, the molybdenum residue does not include a post-etch residue, a post-ash residue, a post-chemical mechanical planarization (CMP) residue, or any combination thereof.

In some embodiments of the device, the molybdenum residue comprises solid particulate matter.

In some embodiments, the device is configured for delivering molybdenum vapor.

In some embodiments, a vapor delivery system comprises any one or more of the device(s) disclosed herein.

In some embodiments, a method comprises obtaining a device configured with a surface configured to be exposed to a vapor, wherein at least a portion of the surface comprises a coating, wherein the coating inhibits mass change at an outer surface of the device from exposure to the vapor; and exposing the surface to the vapor at a temperature of 100° C. or greater.

In some embodiments, the vapor comprises at least one of a metal halide vapor, a metal oxyhalide vapor, or any combination thereof.

In some embodiments, the vapor comprises at least one of molybdenum, tungsten, or any combination thereof.

In some embodiments, the vapor comprises at least one of a molybdenum vapor, a tungsten vapor, or any combination thereof.

In some embodiments of the method, the mass change is a mass gain.

In some embodiments of the method, the coating reduces or inhibits the mass gain in per unit area of equal to or less than 1×10⁻⁵ g mm⁻².

In some embodiments of the method, the molybdenum vapor comprises at least one of MoO₂Cl₂, MoOCl₄, MoCl₅, or any combination thereof.

In some embodiments of the device, the tungsten vapor comprises at least one of WCl₆, WCl₅, WOCl₄, WO₂Cl₃, or any combination thereof.

In some embodiments of the method, the temperature is from 130° C. to 180° C.

In some embodiments of the method, the exposing step is for a duration of 24 hours or less.

In some embodiments of the method, the mass gain is via molybdenum residue which does not include a post-etch residue, a post-ash residue, a post-chemical mechanical planarization (CMP) residue, or any combination thereof.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 shows a comparative nickel-chromium-molybdenum-tungsten alloy (e.g., Hastelloy C22®) after having been exposed to a molybdenum vapor at 170° C. for several hours.

FIG. 2 shows a comparative stainless steel material (mechanically polished 316L SS) having been exposed to a molybdenum vapor at 160° C. for several hours.

FIG. 3 shows a comparative stainless steel material (electropolished polished SS) having been exposed to a molybdenum vapor at 170° C. for several hours.

FIG. 4 shows a comparative Mo foil having been exposed to a molybdenum vapor at 170° C. for several hours.

FIG. 5 shows a comparative fluoropolymer component which has been exposed to a molybdenum vapor at 160° C. for several hours.

FIG. 6 shows an exemplary quartz glass slide which has been exposed to a molybdenum vapor at 160° C. for several hours. After the exposure, blue residue has not formed on the material's surface. There was also no measurable mass gain.

FIG. 7 shows an exemplary aluminum oxide coating on stainless steel which has been exposed to a molybdenum vapor at 160° C. for several hours.

FIG. 8 shows a schematic cross-sectional view of a device according to an embodiment.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in,” “at,” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or
any combination(s) thereof.

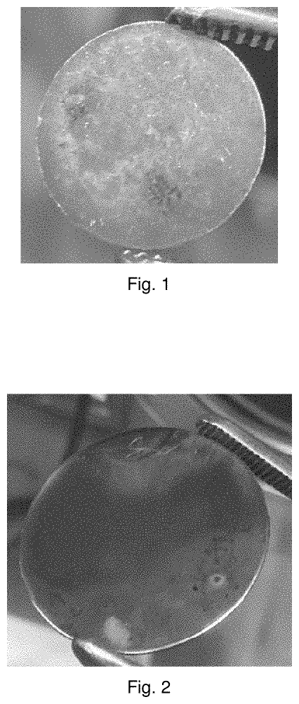

FIG. 1 shows a comparative nickel-chromium-molybdenum-tungsten alloy (e.g., Hastelloy C22®) after having been exposed to a molybdenum vapor at 170° C. for several hours. After the exposure, a blue or bluish residue has formed on the major surface of the exemplary nickel-chromium-molybdenum-tungsten alloy. There was also a measurable mass gain due to the blue residue formed at the surface.

FIG. 2 shows a comparative stainless steel material (mechanically polished 316L SS) having been exposed to a molybdenum vapor at 160° C. for several hours. After the exposure, a blue or bluish residue has formed on the stainless steel material's major surface. There was also a measurable mass gain due to the blue residue formed at the surface.

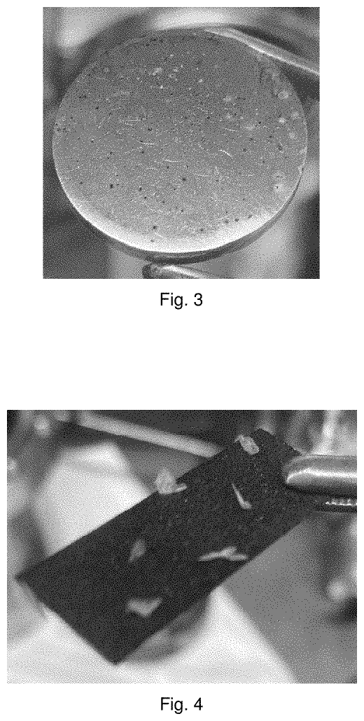

FIG. 3 shows a comparative stainless steel material (electropolished polished SS) having been exposed to a molybdenum vapor at 170° C. for several hours. After the exposure, a blue or bluish residue has formed on the stainless steel material's major surface. In addition, there are corrosion spots that has formed on the material's major surface (shown as black spots). There was also a measurable mass gain due to the blue residue formed at the surface.

FIG. 4 shows a comparative Mo foil having been exposed to a molybdenum vapor at 170° C. for several hours. After the exposure, there is significant blue residue that has formed on the material's major surface, as well as MoO₂Cl₂ crystals. There was also a measurable mass gain due to the blue residue formed at the surface.

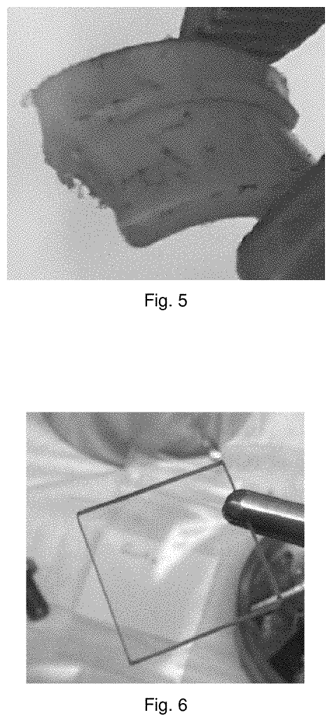

FIG. 5 shows a comparative fluoropolymer component which has been exposed to a molybdenum vapor at 160° C. for several hours. After the exposure, there is significant blue residue spots that has formed on the material's surfaces. There was also a measurable mass gain due to the blue residue formed at the surface.

FIG. 6 shows an exemplary quartz glass slide which has been exposed to a molybdenum vapor at 160° C. for several hours. After the exposure, blue residue has not formed on the material's surface. There was also no measurable mass gain.

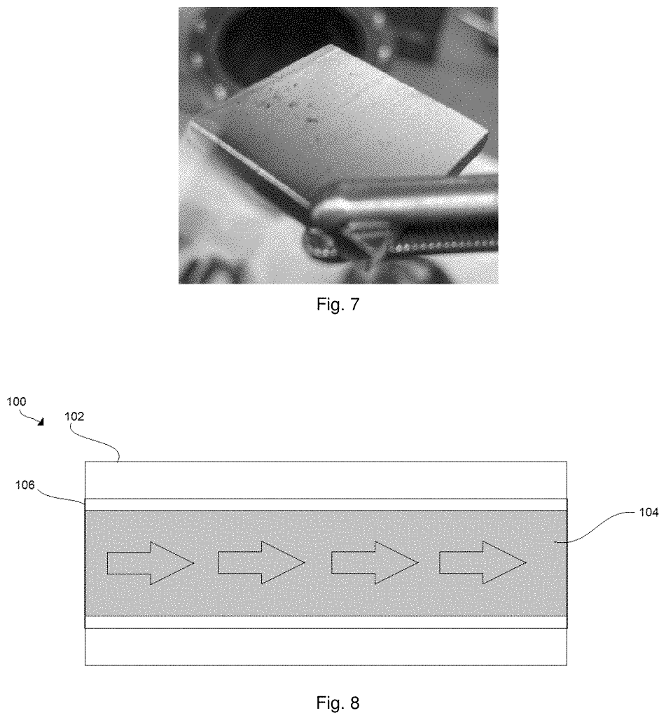

FIG. 7 shows an exemplary aluminum oxide coating on stainless steel which has been exposed to a molybdenum vapor at 160° C. for several hours. After the exposure, very little blue residue has formed on the material's surface. There was also no measurable mass gain. Similarly, AlOx on Si exposed to a molybdenum vapor at 160° C. for several hours results in very little blue residue forming on the material's surface, and no measurable mass gain.

TABLE 1 shown below shows the mass % change on various sample materials after exposure to molybdenum gas at temperatures of 100° C. or greater for several hours.

TABLE 1

| | ΔMass/Surface area |
|---|---|
| Sample | (g/mm²) |
| nickel-chromium- | +9.26E−07 |
| molybdenum-tungsten | |
| alloy | |
| Mech polished SS 316 | +6.81E−07 |
| EP SS 316 | +4.11E−07 |
| Nichrome mesh | +4.62E−06 |
| Mo foil | +1.57E−05 |
| 304L SS | +9.99E−07 |
| Fluoropolymer (e.g. PFA) | +9.09E−06 |
| Quartz | 0.00E+00 |
| AlOx on Si | 0.00E+00 |
| AlOx on SS | 0.00E+00 |
| QCM gold | −3.25E−07 |

Further, exposure to WCl₅ vapor for over 24 hours at 220° C. on various materials shows a mass change on the materials, where there is a mass loss. The mass loss is due to corrosion.

According to some embodiments of devices that are configured to be exposed to chemical vapor(s), such as WCl₅ in some embodiments, such as molybdenum vapors in some other embodiments, a surface of the device that is to be exposed to the chemical vapor(s) is protected by a surface treatment, an added coating, or a combination thereof. While such coating can be understood to reduce or inhibit mass loss due to corrosion, it has been surprising to determine that certain types of surface treatment, added coating, or both can also beneficially reduce the mass gain at the surface. Further, certain types of surface treatment, added coating, or both can also reduce and/or inhibit the blue residue formation on the surface as well.

According to some embodiments, the coating can include at least one of a metal oxide, a metal alloy, an elemental metal, a quartz, or any combination thereof. In some embodiments, the coating comprises a metal oxide, and the metal oxide can be at least one of an aluminum oxide, a silicon oxide, an yttrium oxide, a magnesium oxide, a calcium oxide, a zirconium oxide, a hafnium oxide, a boron oxide, or any combination thereof. In some embodiments, the coating comprises a metal alloy, such as an alloy having less than 20% by weight of molybdenum (Mo) based on a total weight of the metal alloy. In some exemplary embodiments, the coating includes at least one of aluminum (AI), silicon (Si), yttrium (Y), magnesium (Mg), calcium (Ca), zirconium (Zr), hafnium (Hf), boron (B), or any combination thereof. In some exemplary embodiments, the coating includes at least one of yttria, alumina, silica, graphite, sputtered nickel, fluorinated metal alloy, polished stainless steel, borosilicate glass, or any combination thereof.

Accordingly, in various embodiments of devices and methods include a coating on devices configured to be exposed to chemical vapors (such as WCl₅ and/or molybdenum). In some embodiments, the coating reduces or inhibits the mass change (mass gain or mass loss) in per unit area of equal to or less than 1×10⁻⁵ g mm⁻².

FIG. 8 shows an example of a device 100 which is a tube 102 (a schematic cross-sectional view) having an inner cavity 104 defined by a body of the tube 102, wherein the inner cavity 104 is configured to deliver, flow, or provide a pathway for chemical vapors mentioned above. The surface of the tube which defines the inner cavity has a coating 106 (or a surface treatment) according to one or more embodiments disclosed herein.

What is claimed is:

1. A device comprising:
a coating covering at least a portion of the device,
wherein the coating is configured for being exposed to a vapor,
wherein the coating reduces or inhibits mass change at an outer surface of the device from exposure to the vapor.

2. The device of claim 1, wherein the mass change is a mass gain.

3. The device of claim 2, wherein the coating reduces or inhibits the mass gain in per unit area of equal to or less than 1×10⁻⁵ g mm⁻².

4. The device of claim 1, wherein the mass change is a mass loss.

5. The device of claim 1, wherein the vapor comprises at least one of MoO₂Cl₂, MoOCl₄, MoCl₅, WCl₆, WCl₅, WOCl₄, WO₂Cl₃, or any combination thereof.

6. The device of claim 1, wherein the coating comprises at least one of a metal oxide, a metal alloy, an elemental metal, a quartz, or any combination thereof.

7. The device of claim 1, wherein the coating comprises a metal oxide.

8. The device of claim 7, wherein the metal oxide comprises at least one of an aluminum oxide, a silicon oxide, an yttrium oxide, a magnesium oxide, a calcium oxide, a zirconium oxide, a hafnium oxide, a boron oxide, or any combination thereof.

9. The device of claim 1, wherein the coating comprises a metal alloy.

10. The device of claim 9, wherein the metal alloy comprises less than 20% by weight of molybdenum (Mo) based on a total weight of the metal alloy.

11. The device of claim 1, wherein the coating comprises at least one of aluminum (Al), silicon (Si), yttrium (Y), magnesium (Mg), calcium (Ca), zirconium (Zr), hafnium (Hf), boron (B), or any combination thereof.

12. The device of claim 1, wherein the coating comprises at least one of yttria, alumina, silica, graphite, sputtered nickel, fluorinated metal alloy, polished stainless steel, borosilicate glass, or any combination thereof.

13. The device of claim 2, wherein the mass gain is due to at least in part to a molybdenum residue, a tungsten residue, or any combination thereof.

14. The device of claim 13, wherein the coating inhibits formation of the molybdenum residue, tungsten residue, or any combination thereof on the coating when the vapor is at a temperature of 100° C. or greater.

15. The device of claim 13, wherein the molybdenum residue, the tungsten residue, or any combination thereof is a reaction product of a material of the device and the molybdenum vapor.

16. The device of claim 13, wherein the molybdenum residue, the tungsten residue, or any combination thereof does not include a post-etch residue, a post-ash residue, a post-chemical mechanical planarization (CMP) residue, or any combination thereof.

17. The device of claim 13, wherein the molybdenum residue, the tungsten residue, or any combination thereof comprises solid particulate matter.

18. The device of any of claim 1, wherein the device is configured for delivering vapor.

19. A method comprising:
obtaining a device configured with a surface configured to be exposed to a vapor,
wherein at least a portion of the surface comprises a coating,
wherein the coating inhibits mass change at an outer surface of the device from exposure to the vapor; and
exposing the surface to the vapor at a temperature of 100° C. or greater.

20. The method of claim 19, wherein the molybdenum vapor comprises at least one of MoO₂Cl₂, MoOCl₄, MoCl₅, WCl₆, WCl₅, WOCl₄, WO₂Cl₃, or any combination thereof.
